(19) United States
(12) Patent Application Publication
(10) Pub. No.: US 2021/0043783 A1
(43) Pub. Date: Feb. 11, 2021

(54) SOLAR PANEL WITH GRAPHIC COVER FILM AND MANUFACTURING METHODS

(71) Applicant: SBM Solar, Inc., Concord, NC (US)

(72) Inventors: Osbert Cheung, Concord, NC (US); Katharine Tyler Bernart, Concord, NC (US)

(21) Appl. No.: 16/536,481

(22) Filed: Aug. 9, 2019

(51) Int. Cl. H01L 31/0216; C09D 5/30

(52) U.S. Cl. CPC H01L 31/02167; H02S 40/20; C09D 5/30

(57) ABSTRACT

A solar panel construction and method for making the same includes a substrate, an array of solar cells positioned atop the substrate, and a graphical film positioned atop the array of solar cells, the graphical film includes a predetermined pattern of spaced droplets of white pigment applied to a top surface of the graphical film and a predetermined pattern of droplets of colored pigment applied atop at least some of the spaced droplets of white pigment such that each droplet of colored pigment overlaps a droplet of white pigment. The construction may or may not include a separate protective film covering. In use, the white pigment functions to block a portion of the solar cells observed visually while reflecting light back to the solar cells, while the colored pigment applied atop the white pigment creates a desired visual effect such as a camouflage pattern.

### GOVERNMENT RIGHTS

This invention was made with government support under contract No. GTS-S-18-106-SBM Solar awarded by the U.S. Army. The government has/may have certain rights in the invention.

### BACKGROUND OF THE INVENTION

Solar panels are becoming increasingly popular as a source of electrical power in remote locations where access to a local power grid is unavailable, and in local locations in which reliance on a power grid is unwanted or undesirable.

Solar panel constructions typically include an array of solar cells supported on a substrate and covered with a protective layer in the form of plastic or glass. Protective coverings are typically optically transparent so as not to impede or degrade the operation and performance of the underlying solar cells. Most currently available solar cells are dark blue or light black in color. While such colors are suitable for use in applications in which aesthetics are not a primary concern, in other applications such colors are an aesthetic obstacle to installation. In residential installations, for example, homeowners may prefer a construction that blends in with the rooftop and surroundings. In military applications, for example, a camouflaged panel construction is critical and necessary.

Attempts have been made blend the aesthetics of panel constructions with their installation environment. In one example, tinted or graphic cover films have been developed that are applied directly atop the protective cover layer. While such films improve aesthetics, they typically degrade performance by more than 15% and are costly and labor intensive to install. Further, the durability and lifespan of such films has not been fully evaluated, nor has it been determined if films can be removed and replaced without compromising the performance and integrity of the assembly.

Accordingly, what is needed is a solution for enhancing the aesthetics of solar panel constructions.

### SUMMARY OF THE INVENTIVE ASPECTS

In one aspect, the inventive concepts disclosed here are directed to a solar panel construction including a substrate, an array of solar cells positioned atop the substrate, and a graphical film positioned atop the array of solar cells, the graphical film having a predetermined pattern of spaced droplets of white pigment applied on a surface thereof and a predetermined pattern of droplets of colored pigment applied atop at least some of the spaced droplets of white pigment, wherein each droplet of colored pigment overlaps a droplet of white pigment.

In some embodiments, the solar panel construction further includes a protective film applied over the graphical film.

In some embodiments, the spaced droplets of white pigment together cover at least 50% of a surface area of the array of solar cells.

In some embodiments, the spaced droplets of white pigment together cover less than 50% of a surface area of the array of solar cells.

In some embodiments, a ratio of the droplets of white pigment to uncovered surface area of the array of solar cells is about 50:50.

In some embodiments, each individual spaced droplet of white pigment has a diameter between 0.020 inches and 0.035 inches.

In some embodiments, a ratio of droplets of white pigment to space between the droplets of white pigment is between 20:80 and 80:20.

In some embodiments, the graphical film has a thickness between 0.001 inches and 0.020 inches.

In some embodiments, the predetermined pattern of droplets of colored pigment is a camouflage pattern.

In some embodiments, the construction is a lamination including a first adhesive layer between the array of solar cells and the graphical film and a second adhesive layer between the graphical film and the protective film, the first and second adhesive layers bonding the solar panel construction together.

In some embodiments, the substrate is a rigid substrate, the graphical film is one of PET, PVC, acrylic film, vinyl, polycarbonate, ETFS, PVDF or other fluoropolymer, the first and second adhesive layers are one of EVA, TPO and TPU, and the protective film is one of ETFE, PET, fluoro coating PET, fluoropolymer, PVDF, glass, polycarbonate, vinyl, acrylic and PVC.

In another aspect, the inventive concepts disclosed herein are directed to a method for constructing a solar panel assembly including providing a rigid substrate, providing an array of solar cells and positioning the array of solar cells atop the rigid substrate, providing a first adhesive layer and positioning the first adhesive layer atop the array of solar cells, providing a graphical film and positioning the graphical film atop the first adhesive layer, the graphical film comprising a predetermined pattern of spaced droplets of white pigment applied on a surface thereof and a predetermined pattern of droplets of colored pigment applied atop at least some of the spaced droplets of white pigment, wherein each droplet of colored pigment overlaps a droplet of white pigment, and subjecting the solar panel assembly including the rigid substrate, the array of solar cells, the first adhesive layer, and the graphical film to a lamination process to produce a lamination.

In some embodiments, the method further includes, before the step of subjecting the solar panel assembly to a lamination process, the steps of providing a second adhesive layer and positioning the second adhesive layer atop the graphical film and providing a protective film and positioning the protective film atop the second adhesive layer, wherein the step of subjecting the solar panel assembly to a lamination process includes subjecting the solar panel assembly including the rigid substrate, the array of solar cells, the first adhesive layer, the graphical film, the second adhesive layer, and the protective film to the lamination process to produce the lamination.

In some embodiments, the spaced droplets of white pigment of the pattern cover at least 50% of a surface area of the array of solar cells, each individual spaced droplet of white pigment has a diameter between 0.020 inches and 0.035 inches, a ratio of droplets of white pigment to space between the droplets of white pigment is between 20:80 and 80:20, and the graphical film has thickness between 0.001 inches and 0.020 inches.

In some embodiments, the predetermined pattern of droplets of colored pigment is a camouflage pattern.

In aspect, the inventive concepts disclosed herein are directed to a method for producing a graphical film for use in a solar panel construction including providing a film having a thickness between 0.001 inches and 0.020 inches, applying a predetermined pattern of spaced droplets of white pigment on a surface of the film, curing the applied droplets of white pigment, applying a predetermined pattern of droplets of colored pigment atop at least some of the droplets of white pigment, wherein each droplet of colored pigment overlaps a droplet of white pigment, and curing the applied droplets of colored pigment.

In some embodiments, the film is selected from the group consisting of PET, PVC, acrylic film, vinyl, polycarbonate, ETFE, PVDF, or other fluoropolymer.

Embodiments of the inventive concepts can include one or more or any combination of the above aspects, features and configurations.

### BRIEF DESCRIPTION OF THE DRAWINGS

Implementations of the inventive concepts disclosed herein may be better understood when consideration is given to the following detailed description thereof. Such description makes reference to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1 depicts schematically a solar panel construction according to an embodiment of the invention including an integrated graphical film having a pattern applied thereto to produce a visual effect;

FIG. 2 depicts schematically a solar panel construction wherein the graphical film serves as the protective cover layer;

FIG. 3 depicts a face of a graphical film having a pattern of spaced droplets of white pigment applied thereto; and

FIG. 4 depicts the face of the graphical film of FIG. 3 have droplets of a color or colors applied atop at least some of the droplets of white pigment to produce a visual effect such as camouflage.

### DETAILED DESCRIPTION OF EXEMPLARY EMBODIMENTS

The inventive concepts are described hereinafter with reference to the accompanying drawings in which exemplary embodiments are shown. However, the inventive concepts may be embodied in many different forms and should not be construed as limited to the representative embodiments set forth herein.

The inventive concepts disclosed herein are generally directed to solar panel constructions and methods for making the same. The solar panel constructions generally include a graphical film or layer positioned within or atop a laminated stack. In some embodiments, the graphical film layer is positioned within the stack between a layer of solar cells and a protective cover layer, and optionally between first and second adhesive layers for adhering the lamination stack together to form an integrated laminated assembly. In other embodiments, the graphical film itself may function as the cover layer, obviating the need for a separate cover layer or protective film.

The graphical film functions as a support layer for an applied graphical element. The graphical element may be a pattern printed or otherwise applied on a surface of the graphical element. The pattern may be created by applying droplets of pigment of a predetermined color or colors. As used herein, the term “droplet” is intended to denote an individual one of an applied graphical element without limitation to any method of application, material, or shape. In some embodiments, each droplet is generally a dot having a round, elliptical or square shape, among other. In some embodiments, the graphical element includes a plurality of first droplets applied, such as by printing, in a predetermined pattern on a surface of the graphical film to be positioned facing away from the solar cells. The pattern may cover all or a portion of the graphical film depending on the pattern to be applied. For example, some patterns such as camouflage patterns may be applied to cover all of the surface of the graphical film (e.g., as much of the top panel surface as possible), while other patterns such as advertising and logos may be applied to only a portion of the graphical film.

In some embodiments, the pattern includes a plurality of droplets of white pigment applied in spaced apart relation. Examples of pattern types include, but are not limited to, repeating patterns having a dot angle of 0°, repeating patterns having a dot angle of 45°, halftone patterns, other repeating patterns, and random patterns. Patterns may include more than one droplet shape and/or droplet size. The dot spacing may be consistent between dots or may vary from dot-to-dot. In a non-limiting example, the spaced droplets of white pigment together cover at least 50% of a total surface area of the array of solar cells or the surface area of the graphical film. In another non-limiting example, the spaced droplets of white pigment together cover less than 50% of a total surface area of the array of solar cells or graphical film. Other coverage percentages are possible. In another non-limiting example, a ratio of the droplets of white pigment to uncovered surface area of the array of solar cells is about 50:50, although other ratios are possible. In another non-limiting example, each individual spaced droplet of white pigment has a diameter between 0.020 inches and 0.035 inches, although other diameters are possible. In yet another non-limiting example, a ratio of droplets of white pigment to space between the droplets of white pigment is between 20:80 and 80:20, although other ratios are possible.

In use, the droplets of white pigment function to block a portion of the solar cells observed visually, while reflecting light back toward the solar cells. The droplets of white pigment themselves may provide the desired visual effect. In preferred embodiments, the desired visual effect is achieved by providing a predetermined pattern of droplets of colored pigment applied over at least some of the droplets of white pigment. In addition to reflecting light back toward the solar cells, the underlying white enhances the color, among other advantages. The droplets of white pigment serve as a base for applying droplets of colored pigment in an overlapping relationship with the droplets of white pigment. Each droplet of applied white pigment may be overlapped, in total or in part, with a droplet of one or more pigment colors other than white to achieve a desired visual effect. Viewed from above the graphical film the color is visible. Viewed from below the graphical film the white is visible. The desired visual effect may encompass all or part of the film and all or some of the droplets of white pigment may be covered. Examples of color patterns include, but are not limited to, camouflage patterns, pictures, text, logos, etc. and combinations thereof.

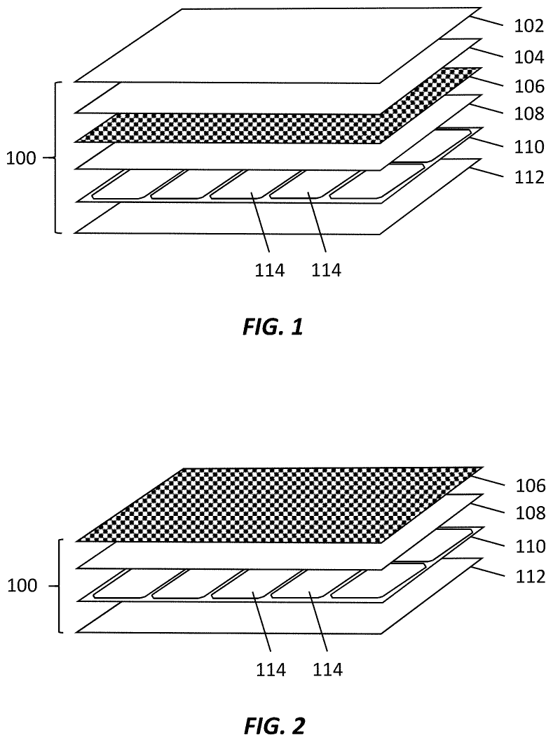

FIG. 1 depicts schematically a non-limiting example of a solar panel construction 100 including a patterned graphical film for achieving a desired visual effect. The panel construction 100 generally includes a substrate layer 112, a solar cell layer 110 including an array of solar cells 114, and a graphical film layer 106. The solar cell layer 110 is positioned atop the substrate layer 112, and the graphical film layer 106 is positioned atop the solar cell layer 104. The individual layers may be adhered together utilizing one or more intermediate adhesive layers 108. For example, an adhesive layer 108 may be positioned intermediate the solar cell layer 110 and the graphical film layer 106 to promote bonding or adhesion, such as during a lamination process. The solar panel construction 100 may optionally include a separate protective cover layer 102 positioned atop the graphical film layer 106 and adhered with an intermediate adhesive layer 104. As shows in FIG. 2, the graphical film layer 106 may serve as the protective layer obviating the need for a separate protective layer.

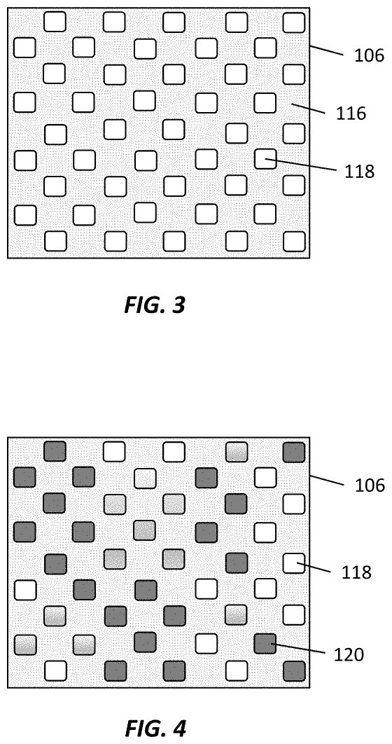

FIG. 3 depicts a non-limiting example of a graphical film layer 106. The graphical film layer 106 has a predetermined pattern printed thereon, and the pattern includes a plurality of individual dots 118 in spaced apart relation. Space between the dots, depicted at reference numeral 116, is not printed on and therefore the underlying solar array can be been through the spacing portions. The pattern shown is a regular pattern of generally square individual dots positioned at a dot angle of 45°. The graphical film layer 106 shown in FIG. 3 having the white dots printed thereon can by itself provide the desired visual effect, or preferably, represents an intermediate processing step with the final graphical film 106 product shown in FIG. 3. The graphical film 106 depicted in FIG. 3 further includes droplets or dots of colored pigment applied in an overlapping arrangement atop at least some of the white dots. For example, reference numeral 120 may represent a droplet of a dark colored pigment applied over a droplet of white pigment, while reference numeral 118 may represent either a droplet of white pigment or a drop of a light-colored pigment applied over a droplet of white pigment. The contrasting colors and pattern shown in FIG. 4 is merely one example and not intended to be limiting.

The substrate is preferably rigid and may be made from plastic, metal, carbon composites, etc., and combinations thereof. The graphical film may constructed from one of polyethylene terephthalate (PET), polyvinyl chloride (PVC), acrylic film, vinyl, polycarbonate, ethylene tetrafluoroethylene (ETFE), polyvinylidene fluoride (PVDF) or other fluoropolymer, and in some embodiments, has a thickness between 0.001 inches and 0.020 inches, although other thicknesses are possible. The adhesive layers may be constructed from one of ethylene vinyl acetate (EVA), thermoplastic polyolefin (TPO), polyoxyethylene (POE), and thermoplastic polyurethane (TPU). The protective film may be constructed from one of ETFE, PET, fluoro coating PET, fluoropolymer, PVDF, glass, polycarbonate, vinyl, acrylic and PVC.

A method for constructing the solar panel assembly depicted in FIG. 1 generally includes providing a rigid substrate, providing an array of solar cells and positioning the array of solar cells atop the rigid substrate, providing a first adhesive layer and positioning the first adhesive layer atop the array of solar cells, providing a graphical film and positioning the graphical film atop the first adhesive layer, the graphical film comprising a predetermined pattern of spaced droplets of white pigment applied on a surface thereof and a predetermined pattern of droplets of colored pigment applied atop at least some of the spaced droplets of white pigment, wherein each droplet of colored pigment overlaps a droplet of white pigment, and subjecting the solar panel assembly including the rigid substrate, the array of solar cells, the first adhesive layer, and the graphical film to a lamination process to produce a lamination. The lamination process optionally includes providing a second adhesive layer and positioning the second adhesive layer atop the graphical film, providing a protective film and positioning the protective film atop the second adhesive layer, and subjecting the solar panel assembly including the rigid substrate, the array of solar cells, the first adhesive layer, the graphical film, the second adhesive layer, and the protective film to the lamination process to produce the lamination.

A method for constructing the graphical film layer itself generally includes providing a film having a thickness between 0.001 inches and 0.020 inches, applying a predetermined pattern of spaced droplets of white pigment on a surface of the film, curing the applied droplets of white pigment, applying a predetermined pattern of droplets of colored pigment atop at least some of the droplets of white pigment, wherein each droplet of colored pigment overlaps a droplet of white pigment, and curing the applied droplets of colored pigment.

The foregoing description provides embodiments of the invention by way of example only. It is envisioned that other embodiments may perform similar functions and/or achieve similar results. Any and all such equivalent embodiments and examples are within the scope of the present invention and are intended to be covered by the appended claims.

1. A solar panel construction, comprising:
a substrate;
an array of solar cells positioned atop the substrate; and
a graphical film positioned atop the array of solar cells, the graphical film having a predetermined pattern of spaced dots of white pigment applied atop a surface thereof and a predetermined pattern of dots of colored pigment applied atop at least some of the spaced dots of white pigment, wherein each dot of colored pigment overlays one of the dots of white pigment such that no dot of colored pigment is applied directly on the surface of the graphical film.

2. The solar panel construction of claim 1, further comprising a protective film applied atop the graphical film.

3. The solar panel construction of claim 1, wherein the spaced dots of white pigment collectively cover at least 50% of a surface area of the array of solar cells.

4. The solar panel construction of claim 1, wherein the spaced dots of white pigment collectively cover less than 50% of a surface area of the array of solar cells.

5. The solar panel construction of claim 1, wherein a ratio of the dots of white pigment to uncovered surface area of the array of solar cells is about 50:50.

6. The solar panel construction of claim 1, wherein each individual dot of white pigment has a diameter between 0.020 inches and 0.035 inches.

7. The solar panel construction of claim 1, wherein a ratio of dots of white pigment to space between the dots of white pigment is between 20:80 and 80:20.

8. The solar panel construction of claim 1, wherein the graphical film has a thickness between 0.001 inches and 0.020 inches.

9. The solar panel construction of claim 1, wherein the dots of colored pigment collectively form a camouflage pattern.

10. The solar panel construction of claim 2, wherein the solar panel construction is a lamination including a first adhesive layer disposed between the array of solar cells and the graphical film and a second adhesive layer disposed between the graphical film and the protective film, the first and second adhesive layers bonding the solar panel construction together.

11. The solar panel construction of claim 10, wherein:
the substrate is a rigid substrate;
the graphical film is one of polyethylene terephthalate (PET), polyvinyl chloride (PVC), acrylic film, vinyl, polycarbonate, ethylene/tetrafluoroethylene copolymer (ETFE), polyvinylidene difluoride (PVDF) or other fluoropolymer;
the first and second adhesive layers are one of ethylene vinyl acetate (EVA), thermoplastic polyolefin (TPO), polyolefin elastomer (POE), and thermoplastic polyurethane (TPU); and
the protective film is one of ETFE, PET, fluoro coating PET, fluoropolymer, PVDF, glass, polycarbonate, vinyl, acrylic and PVC.

12. A method for constructing a solar panel assembly, comprising:
providing a rigid substrate;
providing an array of solar cells and positioning the array of solar cells atop the rigid substrate;
providing a first adhesive layer and positioning the first adhesive layer atop the array of solar cells;
providing a graphical film and positioning the graphical film atop the first adhesive layer, the graphical film comprising a predetermined pattern of spaced droplets of white pigment applied on a surface thereof and a predetermined pattern of droplets of colored pigment applied atop at least some of the spaced droplets of white pigment, wherein each droplet of colored pigment overlaps a droplet of white pigment; and
subjecting the solar panel assembly including the rigid substrate, the array of solar cells, the first adhesive layer, and the graphical film to a lamination process to produce a lamination.

13. The method of claim 12, further comprising, before the step of subjecting the solar panel assembly to a lamination process, the steps of:
providing a second adhesive layer and positioning the second adhesive layer atop the graphical film; and
providing a protective film and positioning the protective film atop the second adhesive layer; and
wherein the step of subjecting the solar panel assembly to a lamination process includes subjecting the solar panel assembly including the rigid substrate, the array of solar cells, the first adhesive layer, the graphical film, the second adhesive layer, and the protective film to the lamination process to produce the lamination.

14. The method of claim 13, wherein the spaced droplets of white pigment of the pattern cover at least 50% of a surface area of the array of solar cells.

15. The method of claim 13, wherein each individual spaced droplet of white pigment has a diameter between 0.020 inches and 0.035 inches.

16. The method of claim 13, wherein a ratio of droplets of white pigment to space between the droplets of white pigment is between 20:80 and 80:20.

17. The method of claim 13, wherein the graphical film has thickness between 0.001 inches and 0.020 inches.

18. The method of claim 13, wherein the pattern of droplets of colored pigment is a camouflage pattern.

19. A method for producing a graphical film for use in a solar panel construction, the method comprising:
providing a film having a thickness between 0.001 inches and 0.020 inches;
applying a predetermined pattern of spaced droplets of white pigment on a surface of the film;
curing the applied droplets of white pigment;
applying a predetermined pattern of droplets of colored pigment atop at least some of the droplets of white pigment, wherein each droplet of colored pigment overlaps a droplet of white pigment; and
curing the applied droplets of colored pigment.

20. The method of claim 19, wherein the film is selected from the group consisting of PET, PVC, acrylic film, vinyl, polycarbonate, ETFE, PVDF, or other fluoropolymer.
